(19) United States
(12) Patent Application Publication
(10) Pub. No.: US 2026/0045934 A1
(43) Pub. Date: Feb. 12, 2026

(54) TRANSCEIVER SWITCHING SYSTEM

(71) Applicant: SKYWORKS SOLUTIONS, INC., Irvine, CA (US)

(72) Inventors: Barkat A. Wani, Irvine, CA (US); Dale A. Beyer, Portland, OR (US); Wai Laing Lee, Portland, OR (US)

(21) Appl. No.: 19/289,284

(22) Filed: Aug. 4, 2025

Related U.S. Application Data
(60) Provisional application No. 63/680,670, filed on Aug. 8, 2024.

(51) Int. Cl. H03H 11/28; H03K 17/56

(52) U.S. Cl. CPC H03H 11/28; H03K 17/56

(57) ABSTRACT

A system for ramping an impedance in a controlled manner, including a trimmed array, an auxiliary array, at least one driver coupled to at least one of the trimmed array or the auxiliary array, an output coupled to the trimmed array and the auxiliary array, and at least one controller coupled to the at least one driver, the trimmed array, and the auxiliary array. The at least one controller is configured to control the at least one driver to provide a drive voltage to at least one of the trimmed array or the auxiliary array, control the auxiliary array to activate in a series of sequential steps, and control the trimmed array to activate in a single step, the trimmed array having a target impedance responsive to activation.

### CROSS-REFERENCE TO RELATED APPLICATIONS

This application claims priority under 35 U.S.C. § 119(e) to U.S. Provisional Patent Application Ser. No. 63/680,670, titled “TRANSCEIVER SWITCHING SYSTEM,” filed Aug. 8, 2024, the entire content of which is incorporated herein by reference.

### BACKGROUND

### 1. Field of the Disclosure

At least one example in accordance with the present disclosure relates generally to switching systems for telecommunication devices, and more specifically, to high speed switching between wired communication devices of and/or within a telecommunication device.

### 2. Discussion of Related Art

Many wired telecommunication devices have transmit and receive channels (or paths) for transmitting and receiving signals. In some examples, the paths may be connected to the same output (e.g., pin or antenna) and therefore to each other.

### SUMMARY

According to at least one aspect of the present disclosure a system for ramping an impedance is presented. The system comprises a trimmed array, an auxiliary array, at least one driver coupled to at least one of the trimmed array or the auxiliary array, an output coupled to the trimmed array and the auxiliary array, and at least one controller coupled to the at least one driver, the trimmed array, and the auxiliary array. The at least one controller is configured to control the at least one driver to provide a drive voltage to at least one of the trimmed array or the auxiliary array, control the auxiliary array to activate in a series of sequential steps, and control the trimmed array to activate in a single step, the trimmed array having a target impedance responsive to activation.

In some examples, the trimmed array includes: one or more switches; one or more impedances, each impedance of the one or more impedances coupled in series with a respective switch of the one or more switches; at least one array input coupled to the one or more switches; and an array output coupled to the one or more impedances. In some examples, controlling the trimmed array to activate includes the at least one controller controlling a subset of the one or more switches to be in a closed state, wherein responsive to the subset of the one or more switches being in the closed state a corresponding subset of the one or more impedances are connected in parallel with one-another with respect to the array output, a total impedance of a parallel combination of the subset of one or more impedances equaling the target impedance. In some examples, the at least one controller is coupled to the one or more switches. In some examples, the auxiliary array includes: one or more switches; one or more impedances, each impedance of the one or more impedances coupled in series with a respective switch of the one or more switches; at least one array input coupled to the one or more switches; and an array output coupled to the one or more impedances. In some examples, controlling the auxiliary array to activate includes the at least one controller sequential controlling each switch of the one or more switches to switch from an open state to a closed state over a period of time. In some examples, the controller is coupled to the one or more switches. In some examples, the driver includes a plurality of pairs of transistors, the auxiliary array includes one or more auxiliary switches, and the trimmed array includes one or more trim switches. In some examples, each pair of transistors of the plurality of pairs of transistors is coupled to a respective switch of the one or more auxiliary switches. In some examples, each pair of transistors of the plurality of pairs of transistors is coupled to a respective switch of the one or more trim switches. In some examples, each pair of transistors of a first subset of the plurality of pairs of transistors is coupled to a respective switch of the one or more trim switches, and each pair of transistors of a second subset of the plurality of pairs of transistors is coupled to a respective switch of the one or more auxiliary switches. In some examples, the at least one controller is further configured to deactivate the auxiliary array responsive to activating the trimmed array. In some examples, responsive to activating each auxiliary impedance of the auxiliary array, the auxiliary array has the target impedance.

According to at least one aspect of the present disclosure, a system for controlling reflections in a telecommunication circuit is presented, comprising: a transmitter configured to transmit a signal using a driver; a receiver that can reflect a reflected signal based on the signal back to the transmitter; an auxiliary array coupled between the transmitter and the receiver, the auxiliary array including a plurality of auxiliary impedances and a plurality of auxiliary switches, each auxiliary switch coupled to a respective auxiliary impedance; a trimmed array coupled between the transmitter and the receiver, the trimmed array including a plurality of trimmed impedances and a plurality of trimmed switches, each trimmed switch coupled to a respective trimmed impedance; and at least one controller coupled to the driver, the plurality of auxiliary switches, and the plurality of trimmed switches, the at least one controller configured to perform a set of operations including sequentially controlling each auxiliary switch of the plurality of auxiliary switches to be in a closed state, responsive to each auxiliary switch of the plurality of auxiliary switches being in the closed state, controlling a subset of the plurality of trimmed switches to be in the closed state, and responsive to controlling the subset of the plurality of trimmed switches to be in the closed state, controlling each auxiliary switch of the plurality of auxiliary switches to be in an open state.

In some examples the driver includes a plurality of pairs of transistors, each pair of transistors of the plurality of pairs of transistors being coupled to a respective switch of the plurality of auxiliary switches and the plurality of trimmed switches. In some examples, the driver is coupled to each transistor of the plurality of pairs of transistors and is configured to provide a control signal to each respective gate of each respective transistor. In some examples, a first transistor of each pair of transistors of the plurality of transistors is coupled to a first voltage bus, and a second transistor of each pair of transistors of the plurality of transistors is coupled a second voltage bus, a first voltage of the first voltage bus being greater than a second voltage of the second voltage bus. In some examples, the at least one controller is configured to perform the set of operations responsive to determining that the transmitter is transmitting at least part of the signal. In some examples, responsive to closing each auxiliary switch of the plurality of auxiliary switches, the auxiliary array has a same impedance as the trimmed array responsive to the subset of the plurality of trimmed switches being in the closed state.

According to at least one aspect of the present disclosure, a method of adjusting an impedance in a total number of discrete steps is presented, comprising: providing a transmit signal at an output of a driver; responsive to providing the transmit signal, sequentially closing each auxiliary switch of an auxiliary impedance array, each auxiliary switch being configured to couple a corresponding auxiliary impedance to the output; responsive to closing all auxiliary switches of the auxiliary impedance array, closing a subset of trimmed switches of a trimmed impedance array, each trimmed switch being configured to couple a corresponding trimmed impedance to the output; and responsive to closing the subset of trimmed switches, opening each auxiliary switch of the auxiliary impedance array.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a trimmed impedance array according to an example;

FIG. 2 illustrates a trimmed impedance array according to an example;

FIG. 3 illustrates an auxiliary impedance array according to an example;

FIG. 4 illustrates a timing diagram according to an example;

FIG. 5 illustrates a graph comparing voltages according to an example;

FIG. 6 illustrates a graph comparing voltages according to an example; and

FIG. 7 illustrates a process for ramping a voltage according to an example.

### DETAILED DESCRIPTION

In examples discussed herein, wired telecommunication systems, which may generally operate at high frequencies, may be equipped with drivers (e.g., for the transmit paths) and/or receivers (e.g., for the receive path). In some examples discussed herein, drivers and/or receivers may step their output voltage up or down over a period of time between the beginning and/or end of transmission and/or between the beginning and/or end of a subset of the time for transmission, such as during the transmission of a bit or other data unit. In many example, this voltage ramping (i.e., stepping up or down the voltage) will coincide with the period of time allocated for the first bit and/or the last bit in a transmission (but not, for example, to the period of times allocated for bits between the first and last bits).

Ramping the voltage during the beginning of transmission can reduce reflections that might occur, or may make controlling the behavior of reflections (a form of microwave effect) more manageable and predictable, allowing reflections to be mitigated. In some examples, ramping up the voltage of the driver occurs over the course of the transmission of the first bit, and ramping the voltage down occurs over the course of the transmission of the last bit, though ramping up or down may occur over other periods (e.g., periods of time, over numbers of bits, and so forth). In some examples, the rise time (e.g., the time taken to ramp the voltage up) of the transmitted bit voltage (e.g., the voltage of the first bit) may be greater than twice the propagation delay of the communication channel. This may ensure that reflection from the far end of the channel comes back within the rise time of the transmitted bit and thus can be absorbed by the matched output impedance of the driver.

For example, in source terminated systems where the transmit output driver impedance is matched to the channel impedance, but the receivers are unterminated, the transmit signal (i.e., the signal being transmitted from one IC to another) may see a voltage divider at the output with an impedance of

$$\frac{{Z}_{o u t}}{{Z}_{0} + {Z}_{out}} \qquad ( 1 )$$

where Zₒᵤₜ is the impedance of the source termination and the Z₀ is the impedance of the bus (e.g., the line on which the transmit signal is present during transmission). In some examples, the receiver is also unterminated. At the receiver, the reflection coefficient may be 1 or approximately 1 (e.g., 1+/−10%, 1+−5%, and so forth). The receiver may therefore reflect the transmit signal at a high amplitude (possibly up to more than twice the amplitude of the transmit signal itself), which can create noise, unintentionally trigger the receivers, distort the transmit signal, damage the transmitter, damage the receiver (or another receiver on the bus), and so forth.

However, if the transmit signal has a sufficient rise time (e.g., a rise time more than twice that of the propagation delay), whether continuous or in discrete steps, the source termination (e.g., Zₒᵤₜ) may have time to absorb the reflected signal, which reduces the risk of damage, distortion, unintentionally triggering of the receiver, and/or error.

Having a discrete number of steps in the transmitted signal's rise and fall times allows for absorption of reflected signals at least in part because if the reflection arrives during the same step which creates it, the reflection may be absorbed if the impedance of the transmitter matches or is close to the channel impedance. Smaller steps and larger numbers of steps also assist with absorption and signal integrity; however, circuit area limitations and complexity limit the number of steps than can be practically implemented. Nonetheless, for many applications four to five steps are sufficient.

Methods disclosed herein provide a sufficient rise time for a signal (e.g., the transmit signal) by providing the driver of the signal with a trimmed array of impedances, where each impedance is coupled to a switch, such that the impedances can be turned on one at a time during the rise and/or fall time of the transmitted signal until the target impedance is reached. In many examples, the rise time may be implemented as a number of discrete steps, such as those described above. The trimmed array of impedance may be used to match the impedance of the channel by switching to the appropriate impedance or set of impedances.

However, trimmed impedance arrays can suffer from various issues. In particular, the trimmed impedance array may not be able to provide the desired number of steps (or, more generally, the desired ramp up intervals).

For example, during manufacture a trimmed impedance array may have 5 impedances incorporated into it where a combination of these impedances provides the desired output impedance (e.g., 50 Ohms) in a sequence of steps corresponding to the desired rise and/or fall time of the signal (e.g., the ramping up or down of the voltage during the first or last transmitted bit, respectively). For example, for the purpose of absorbing reflections, the impedances may switch on in a sequence where each of the individual impedances are turned on according to the rise and/or fall time of the signal (as discussed above, e.g., with the signal ramping up or down). In an ideal situation, the trimmed impedance array should have the desired target impedance when all of the impedances are switched on (e.g., all 3, 4, 5, 10, and so forth). But, due to manufacturing and process variances, it is likely (and inevitable in any sample of meaningful size) that some of the impedances in the array will be too small or too large. As a result, various undesirable cases can arise. For example, in one undesirable case, when all impedances are switched on, the trimmed impedance array may have an overall impedance below the target impedance. In such a case, the trimmed impedance array cannot switch on all the impedances. Thus, instead of, for example, five steps to reach the target impedance during the rise or fall time, it may take less than five steps—for example, only two steps to reach the target impedance. In such a case, the number of steps may not be adequate to ensure the source termination has time to absorb the reflected signal.

Methods disclosed herein provide a solution to the problem of using a trimmed impedance array. An auxiliary array is coupled to the output, the auxiliary array having one or more additional impedances. The auxiliary array may be untrimmed and/or built with a combination of impedances that do not need to meet the same precision as the main trimmed array.

The auxiliary array may, during the rise and/or fall time of the transmitted signal, switch through a sequence of steps, with an impedance in the auxiliary array being switched on (or off) at each step to arrive at or near the target impedance (e.g., 50 Ohms or any other desired value). When the auxiliary array is completely switched on, the main trimmed array with the target impedance (at a higher precision) may be switched on and the auxiliary array switched off). This can ensure a minimum number of steps (e.g., 4, 5, or any other number) during the rise and/or fall time of the signal.

Each impedance may be coupled to its own auxiliary driver, or they may be coupled to the same driver. Each impedance may have a switch. These auxiliary impedances can be switched on one at time, and then the trimmed impedance array may be switched on. Once the trimmed impedance array is switched on, the auxiliary impedances may be switched off. This configuration guarantees a minimum number of steps equal to the number of impedances in the auxiliary array.

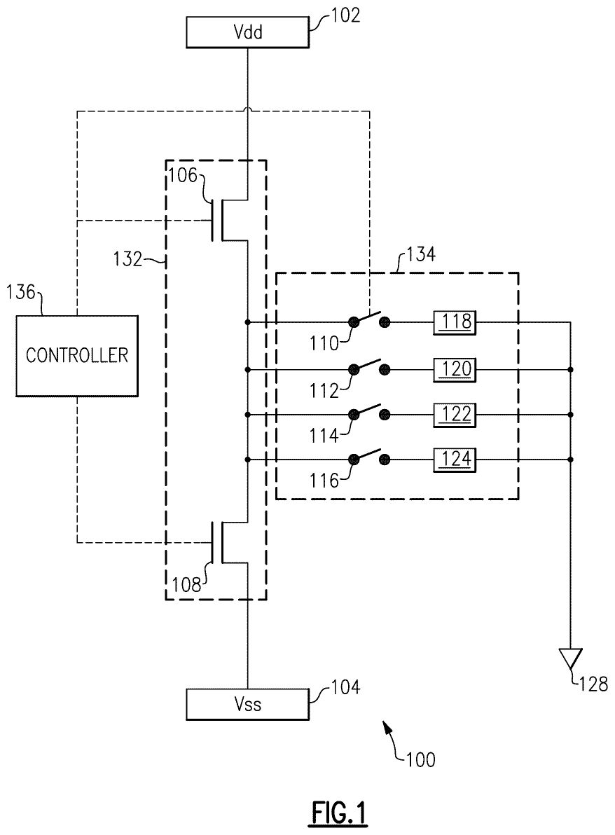

FIG. 1 illustrates a trimmed impedance array 100 according to an example. The trimmed impedance array 100 uses multiple impedances in parallel to achieve a target impedance with relatively high precision. The trimmed impedance array 100 includes a first input 102, a second input 104, a first transistor 106, a second transistor 108, a first switch 110, a second switch 112, a third switch 114, a fourth switch 116, a first impedance 118, a second impedance 120, a third impedance 122, a fourth impedance 124, an output 128, and a controller 130.

The components of the trimmed impedance array 100 are divided into two general parts, a driver 132, and an array 134. The driver 132 includes the transistors 106, 108 which are coupled to voltage sources and function as switches. The array 134 includes the switches 110-116 and impedances 118-124. The driver 132 drives the output signal by providing a driving voltage. The array 134 contains the components of the circuit which facilitate the step-up or ramp-up procedure.

The first input 102 is coupled to the first transistor 106. The second input 104 is coupled to the second transistor 108. The first transistor 106 is further coupled to the first switch 110, second switch 112, third switch 114, and fourth switch 116, in addition to the second transistor 108. The second transistor 108 is further coupled to the first switch 110, second switch 112, third switch 114, and fourth switch 116, in addition to the first transistor 106. The first switch 110 is coupled to the first impedance. The second switch 112 is coupled to the second impedance 120, the third switch 114 is coupled to the third impedance 122, and the fourth switch is coupled to the fourth impedance 124. Each of the first impedance 118, second impedance 120, third impedance 122, and fourth impedance 124 is further coupled to the output 128.

The first input 102 is configured to provide a voltage to one of the drain or source of the first transistor 106. It will be appreciated that most FET transistors are symmetrical devices. Accordingly, herein, the term “first terminal” will refer to one of the source or drain, and the term “second terminal” will refer to the other of the source or drain for a given transistor. The second input 104 is configured to provide a voltage to one of the source or drain of the second transistor 108. When the first transistor 106 is conducting (e.g., on), a conducting path from the first input 102 to the output 128 may be provided by closing one or more of the switches 110-116. When the second transistor 108 is conducting (e.g., on), a conducting path from the second input 104 to the output 128 may be provided by closing one or more of the switches 110-116. In some examples, the first transistor 106 and/or the second transistor 108 may be any other type of switch, such as multi-terminal switch (e.g., double-pole double-throw), a relay, and so forth.

The output 128 is configured to provide the signal from the trimmed impedance array 100 to another circuit or circuit element, such as a receiver.

The first switch 110 may be closed to provide a conducting path through the first switch 110 and the first impedance 118 to the output 128. The second switch 110 may be closed to provide a conducting path through the second switch 110 and the second impedance 120 to the output 128. The third switch 112 may be closed to provide a conducting path through the third switch 112 through the third impedance 122 to the output 128. The fourth switch 116 may be closed to provide a conducting path through the fourth switch 116 and the fourth impedance 124 to the output 128.

The impedances 118-124 may be real (e.g. resistances), and may be identical (e.g., have the same value of impedances) or different (e.g., have different impedances). When one switch is closed, the impedance between the transistors 106, 108 and the output 128 (the “trimmed impedance”) may be equal to the impedance corresponding to said switch. For example, when the first switch 110 is closed, and the other switches 112-116 are open, the trimmed impedance may be substantially equal to impedance of the first impedance 118 (e.g., ignoring the impedance of the switch 110). When multiple switches are closed, the trimmed impedance may be determined based on the parallel combinations of the impedances corresponding to the closed switches. In general, a parallel impedance may be determined according to the following equations:

$$\frac{1}{{Z}_{T}} = \frac{1}{{Z}_{1}} + \frac{1}{{Z}_{2}} + ⋯ + \frac{1}{{Z}_{n}} \qquad ( 2 )$$

where Z_{T} is the total impedance, Z₁ is the first of the parallel impedances, Z₂ is the second of the parallel impedances, and so on, to Zₙ, the n^{th} parallel impedance of the parallel impedances.

Because of the properties of equation (2), when multiple impedances are connected in parallel, the total impedance (Z_{T}) will always be less than the smallest of the parallel coupled impedances. For example, an impedance of 10⁶ Ohms (Ω) coupled in parallel with an impedance of 10Ω and an impedance of 1000Ω will always result in an effective impedance less than 10Ω. As a result, coupling multiple impedances in parallel is one way to create an overall impedance with a desired resistance without having to manufacture specialized impedances with the desired impedance. For example, a 50Ω resistor could be manufactured to have precisely 50Ω of resistance at potentially great cost due to process errors and manufacturing difficulties (as such difficulties may cause most or many of the resistors manufactured this way to vary by unacceptable amounts from 50Ω), or twenty 1000Ω impedances could be coupled in parallel. The twenty parallel 1000Ω impedances may still suffer from manufacturing and process errors that result in some of the impedances having more or less than resistances of 1000Ω, however on average the deviations from 1000Ω will tend to balance out to zero or a number relatively near zero, thus giving a final resistance of the parallel combination of twenty impedances a value reliably and/or acceptably close to 50Ω, or exactly 50Ω.

FIG. 1 includes four impedances 118-124, thus—for example—each could have a 200Ω resistance if the target resistance for the parallel combination of impedances 118-124 is 50Ω. In general, the values of the impedances 118-124 may be chosen so that the parallel combination of the impedances 118-124 equals the desired impedance.

However, as mentioned above, due to process and manufacturing errors (e.g., real-world variations and difficulties in guaranteeing uniform or exact values for batches of resistors or other impedances), in some examples the parallel combination of the impedances 118-124 may be too low, meaning that not every switch 110-116 can be closed. For example, if the effective impedances have an average resistance of 100Ω and the target resistance for the parallel combination is 50Ω, only two of the switches 110-116 could be closed. This would limit the number of steps in the ramp-up process to two steps (one for each switch closed) which would be, at least in some circumstances, too few steps for the source termination to absorb reflections.

The controller 136 is coupled to the transistors 106, 108 and the switches 110-116, and is configured to control the states of the transistors 106, 108 and switches 110-116. For example, the controller 136 may be configured to provide a control signal to the gates of the transistors 106, 108, thereby controlling whether the transistors 106, 108 are in a conducting or non-conducting state.

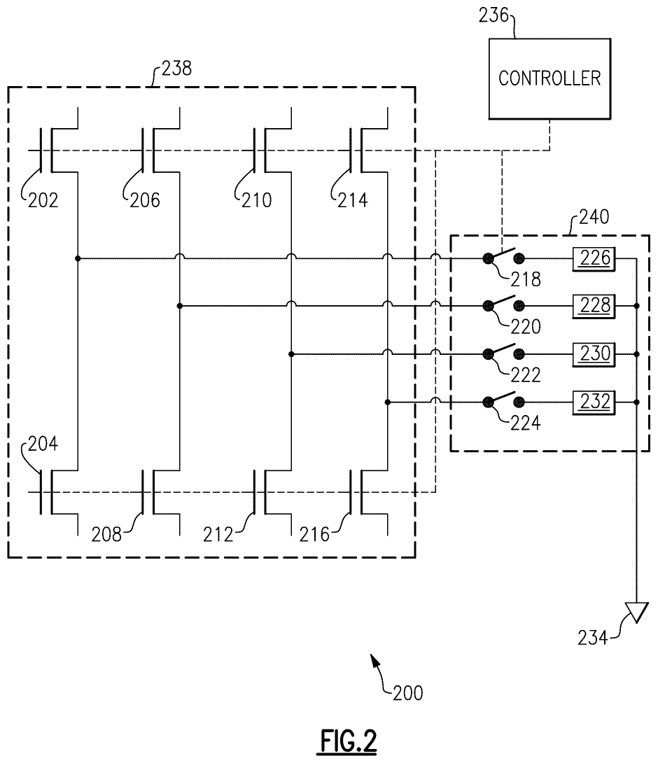

FIG. 2 illustrates a trimmed impedance array 200 according to an example. The trimmed impedance array 200 operates similarly to the trimmed impedance array 100 of FIG. 1, except that each switch is now coupled to a respective driver output instead of the same driver output (that is, in FIG. 1 the switches 110-116 are all coupled to the first transistor 106 and second transistor 108, whereas in FIG. 2 each switch is coupled to a respective pair of transistors).

The trimmed impedance array 200 includes a first transistor 202, a second transistor 204, a third transistor 206, a fourth transistor 208, a fifth transistor 210, a sixth transistor 212, a seventh transistor 214, an eighth transistor 216, a first switch 218, a second switch 220, a third switch 222, a fourth switch 224, a first impedance 226, a second impedance 228, a third impedance 230, a fourth impedance 232, and an output 234.

The components of the trimmed impedance array 200 are divided into two general parts, a driver 238, and an array 240. The driver 238 includes the transistors 202-216 which are coupled to voltage sources and function as switches. The array 240 includes the switches 218-224 and impedances 226-243. The driver 238 drives the output signal by providing a driving voltage. The array 240 contains the components of the circuit which facilitate the step-up or ramp-up procedure.

The first transistor 202 and second transistor 204 are coupled to the first switch 218 via respective first terminals. The third transistor 206 and fourth transistor 208 are coupled to the second switch 220 via respective first terminals. The fifth transistor 210 and sixth transistor 212 are coupled to the third switch 222 via respective first terminals. The seventh transistor 214 and eighth transistor 216 are coupled to the fourth switch 224 via respective first terminals. The first transistor 202, third transistor 206, fifth transistor 210, and seventh transistor 214 may also be coupled via respective second terminals to the same or respective busses, wherein the busses are configured to provide first voltages to those transistors. The second transistor 204, fourth transistor 208, sixth transistor 212, and eighth transistor 216 are coupled via respective second terminals to the same or respective busses, wherein the busses are configured to provide second voltages to those transistors. The gates of the transistors may be coupled to a control circuit configured to selectively provide voltages to the gates and thereby operate the transistors as switches.

The first switch 218 is coupled to the first impedance 226. The second switch 220 is coupled to the second impedance 228, the third switch 222 is coupled to the third impedance 230, and the fourth switch 224 is coupled to the fourth impedance 232. Each impedance 226-232 is coupled to the output 234.

The output 234 may be coupled to another circuit or circuit element, such as a connection pin for wired communication.

When the first switch 218 is closed, this creates a conducting path through the first switch 218 and the first impedance 226 to the output 234. When the second switch 220 is closed, this creates a conducting path through the second switch 220 and the second impedance 228 to the output 234. When the third switch 222 is closed, this creates a conducting path through the third switch 222 and the third impedance 230 to the output 234. When the fourth switch 224 is closed, this creates a conducting path through the fourth switch 224 and the fourth impedance 232 to the output 234.

In some examples, the switches 218-224 may be omitted and the respective impedances 226-232 coupled to those switches 218-224 may instead be directly (rather than switchably) coupled to the respective transistors 202-216.

As the switches 218-224 are closed, the impedances 226-232 are coupled to the output 234 in a manner that is equivalent or nearly equivalent to being coupled to the output 234 in parallel with one another. Alternatively, where the switches 218-224 are omitted, setting a transistor 202-216 to a conducting state may be equivalent to closing a switch.

As with FIG. 1, when the impedances are part of a conducting path, the total impedance will depend on which and how many of the impedances 226-232 are part of a conducting path to the output 234 at a time. The overall impedance may be given by equation (2) above.

The controller 236 is coupled to the transistors 202-216 and the switches 218-224, and is configured to control the states of the transistors 202-216 and switches 218-224. For example, the controller 236 may be configured to provide a control signal to the gates of the transistors 202-216, thereby controlling whether the transistors 202-216 are in a conducting or non-conducting state.

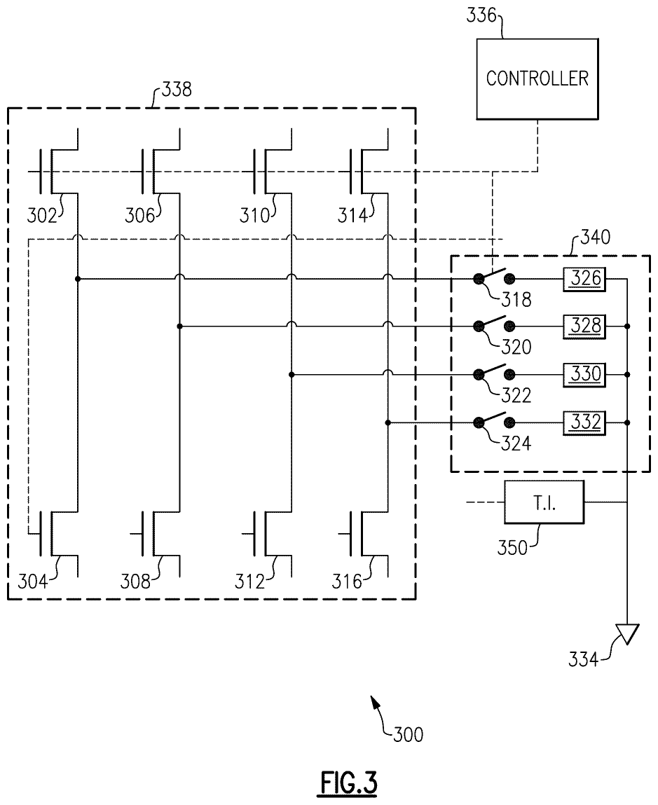

FIG. 3 illustrates an auxiliary array system 300 (“auxiliary array 300”) according to an example. The auxiliary array 300 includes a trimmed impedance array 350 which, in some examples, may be implemented using the trimmed impedance array 100 of FIG. 1 or the trimmed impedance array 200 of FIG. 2. The auxiliary array 300 also includes a first transistor 302, a second transistor 304, a third transistor 306, a fourth transistor 308, a fifth transistor 310, a sixth transistor 312, a seventh transistor 314, an eighth transistor 316, a first switch 318, a second switch 320, a third switch 322, a fourth switch 324, a first impedance 326, a second impedance 328, a third impedance 330, a fourth impedance 332, and an output 334.

The components of the auxiliary impedance array 300 are divided into two general parts, a driver 338, and an array 340. The driver 338 includes the transistors 302-316 which are coupled to voltage sources and function as switches. The array 340 includes the switches 318-324 and impedances 326-333. The driver 338 drives the output signal by providing a driving voltage. The array 340 contains the components of the circuit which facilitate the step-up or ramp-up procedure.

The auxiliary array 300 has a plurality of impedances that may be trimmed or may not be trimmed (but, in some examples, are not trimmed). The impedances 326-332 may always be available whereas, in the case of the trimmed impedance array 350, some of the impedances may not be available because the impedance of the trimmed impedance array 350 would drop too low or would not have enough steps. The auxiliary array 300 therefore adds at least four steps during the ramp-up process—though auxiliary arrays with fewer steps or more steps are also within the scope of this disclosure. The auxiliary array 300 can therefore ensure that, during the ramp-up process, there are a minimum number of steps equal to at least the number of impedances in the auxiliary array 300. Furthermore, as the auxiliary array 300 impedances 326-332 do not need to be trimmed, and can be larger or easier to manufacture than the impedances of the trimmed impedance array 350, the auxiliary array 300 can also be less expensive to produce than using only a trimmed impedance array to get the desired or acceptable number of steps.

The first transistor 302 and the second transistor 304 are coupled to the first switch 318 via respective sources and/or drains. The third transistor 306 and fourth transistor 308 are coupled to the second switch 320 via respective sources and/or drains. The fifth transistor 310 and sixth transistor 312 are coupled to the third switch 322 via respective sources and/or drains. The seventh transistor 314 and eighth transistor 316 are coupled to the fourth switch 324 via respective sources and/or drains. The first switch 318 is coupled to the first impedance 326, the second switch 320 is coupled to the second impedance 328, the third switch 322 is coupled to the third impedance 330, and the fourth switch 324 is coupled to the fourth impedance 332. The impedances 326-332 and the trimmed impedance array 350 are coupled to the output 334.

When the first switch 318 is closed, this creates a conducting path through the first switch 318 and the first impedance 326 to the output 334. When the second switch 320 is closed, this creates a conducting path through the second switch 320 and the second impedance 328 to the output 334. When the third switch 322 is closed, this creates a conducting path through the third switch 322 and the third impedance 330 to the output 334. When the fourth switch 324 is closed, this creates a conducting path through the fourth switch 324 and the fourth impedance 332 to the output 334. In some examples the switches 318-324 may be omitted. In examples where the switches 318-324 are omitted, the transistors 302-316 may act as the switches would have.

In one example of operation of the auxiliary array 300, during the ramp up procedure the switches 318-324 may be initialized to an open state. The first switch 318 may be closed, followed by the second switch 320 a short time later (e.g., microseconds, nanoseconds, or even shorter periods of time, and so forth), then the third switch 322 a short time after the second switch 320, and the fourth switch 324 a short time after the third switch 322. Once each switch 318-324 is closed, the trimmed impedance array 350 may be activated, and once activated, the switches 318-324 may be returned to an open state.

When the trimmed impedance array 350 is activated, this may be equivalent to closing a subset of the switches within the trimmed impedance array 350 such that the overall impedance of the trimmed impedance array 350 matches or is close to the target impedance and/or no further switches need be closed within the trimmed impedance array 350. In some examples, the trimmed impedance array 350 may be activated and the switches 318-324 in a closed state during an overlapping period of time, resulting in an overall source termination impedance that is less than the target impedance. However, in such examples, the switches 318-324 may be opened relatively rapidly so that the period of overlap is minimal (e.g., nanoseconds or less than nanoseconds). In other examples, there may be no overlap period because the trimmed impedance array 350 may be activated simultaneously with the switches 318-324 being opened.

In some examples, the drivers for the trimmed impedance array 350 may be the same as those for the auxiliary array 300. That is, the first switch of the trimmed impedance array 350 may be coupled to the first transistor 302 and second transistor 304, the second switch of the trimmed impedance array 350 may be coupled to the third transistor 306 and fourth transistor 308, and so forth. However, in some examples, the drivers for the trimmed impedance array 350 may not be the same as those for the auxiliary array 300.

The controller 336 is coupled to the transistors 302-316 and the switches 318-324, and is configured to control the states of the transistors 302-316 and switches 318-324. For example, the controller 336 may be configured to provide a control signal to the gates of the transistors 302-316, thereby controlling whether the transistors 302-316 are in a conducting or non-conducting state.

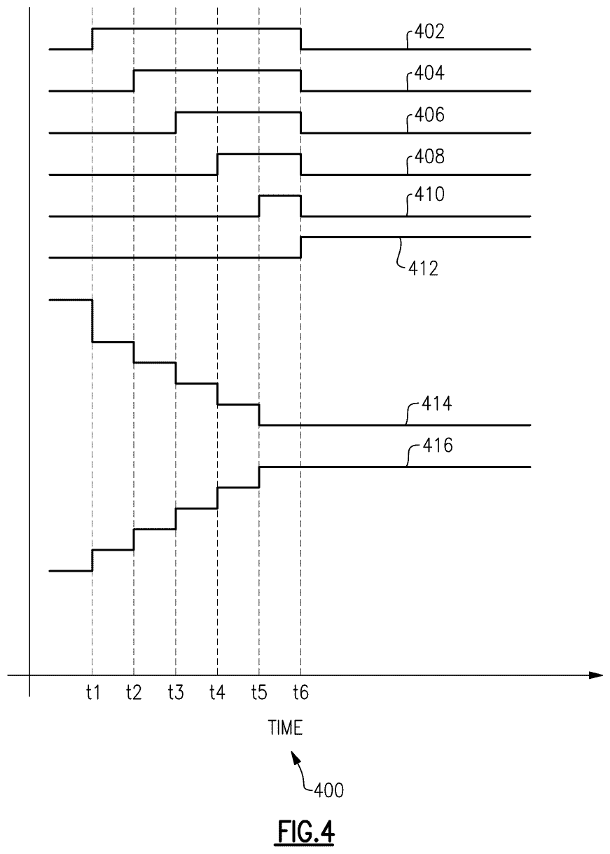

FIG. 4 illustrates a timing diagram corresponding to the impedance and voltage at the output of a driver during a time step corresponding to ramping up or down the voltage, according to an example. FIG. 4 includes a first trace 402, a second trace 404, a third trace 406, a fourth trace 408, a fifth trace 410, a sixth trace 412, a seventh trace 414, and an eighth trace 416.

The first trace 402 corresponds to a first impedance of an auxiliary array. The second trace 404 corresponds to a second impedance of the auxiliary array. The third trace 406 corresponds to a third impedance of the auxiliary array. The fourth trace 408 corresponds to a fourth impedance of the auxiliary array. The fifth impedance 410 corresponds to a fifth impedance of the auxiliary array. Each of the first through fifth traces 402-410 has a high state and a low state. When in the high state, the corresponding impedance is “on,” that is, contributing to the impedance of the auxiliary driver. When in the low state, the corresponding impedance is “off,” that is not contributing meaningfully to the impedance of the auxiliary driver. The first trace 402 goes from low to high at a first time, t1. The second trace 404 goes from a low to high state at a second time, t2, following the first time. The third trace 406 goes from low to high at a third time, t3, following the second time. The fourth trace 408 goes from low to high at a fourth time, t4, following the third time. The fifth trace 410 goes from low to high at a fifth time, t5, following the fourth time. Each of the first through fifth traces 402-410 switches from high to low at a sixth time, t6, following the fifth time.

The sixth trace 412 corresponds to the trimmed impedance and/or corresponding driver. When low, the trimmed impedance is not contributing to an output impedance of the driver, and when high the trimmed impedance contributes to an output impedance of the driver. The sixth trace 412 switches from low to high at the sixth time. Thus, when the trimmed impedance switches on, the auxiliary impedance is switching off or has switched off.

The seventh trace 414 corresponds to the impedance of the driver. The impedance of the driver falls as the impedances of the auxiliary array are switched on, before reaching the target impedance (e.g., approximately 50 Ohms in some examples). In some examples, the overall impedance of the driver may fluctuate briefly during the transition from the auxiliary impedance to the trimmed impedance (e.g., at time t6). Furthermore, in some examples, the impedance after the sixth time may be slightly higher or lower than the impedance during the period from the fifth time to the sixth time.

The eighth trace 416 corresponds to the voltage at the output of the driver. The voltage increases at each of the first, second, third, fourth, and fifth times. In some examples, the voltage may change slightly (being slightly higher or lower) after the sixth time compared to the period of time between the fifth and sixth times.

Note that, in some examples, the first time through sixth time may correspond to a ramping up or ramping down time as discussed above.

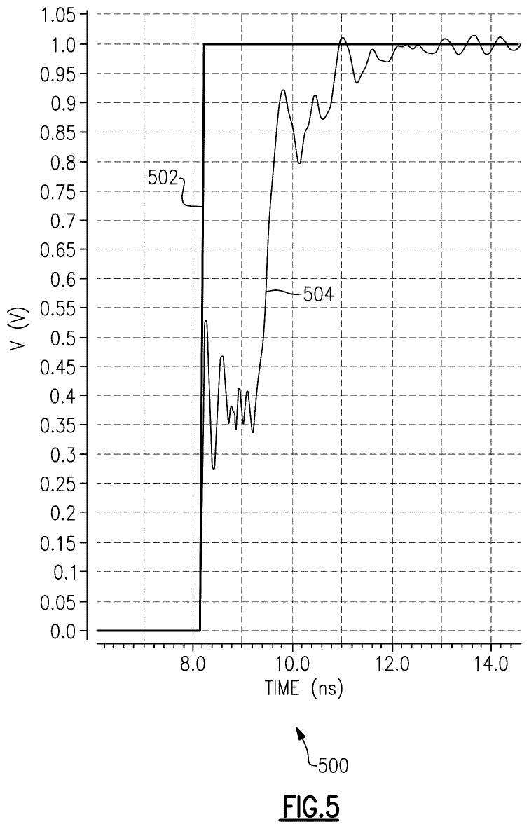

FIG. 5 illustrates a graph 500 where the driver output voltage is ramped up in a single step according to an example. The graph has a first axis (the X-axis) indicating time in nanoseconds (ns). The graph has a second axis (the Y-axis) indicating voltage in volts (V). The graph 500 further includes a first trace 502 and a second trace 504. The first trace 502 indicates the driver output voltage, and the second trace 504 shows the impact of the reflections on the drive signal. That is, the first trace 502 is the driver output voltage under ideal conditions, and the second trace 504 is the driver output voltage after accounting for the effects of the reflections (e.g., from the receiver).

The first trace 502 shows the driver output voltage when it is ramped-up in a single step. Under ideal conditions, the driver output voltage would increase from 0V to 1V in about one-tenth of a nanosecond, and then would remain stable at 1V for the duration of the driver output.

However, the second trace 504 shows that due to reflections, the actual output voltage, instead of matching the driver output voltage, oscillates substantially over a period of about 4 ns and continues to oscillate thereafter. In particular, there is an oscillation of about 0.25V between 8 ns and 9 ns, and then a jump of approximately 0.6V from 9 ns to 10 ns, followed by further oscillations with magnitudes of 0.1V to about 0.01V.

With respect to FIG. 5, the transmission line model was used to simulate reflections and microwave effects that a wired high speed communication channel exhibits during the simulations and testing that generated the corresponding data.

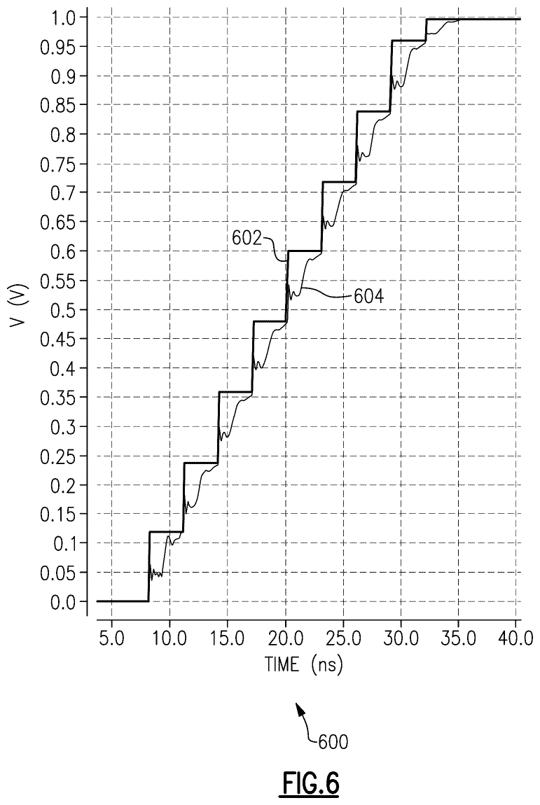

FIG. 6 illustrates a graph 600 where the driver output voltage is ramped up in multiple steps according to an example. This graph 600 reflects how the auxiliary impedance arrays can work. The graph 600 includes a first trace 602 indicating the driver output voltage under ideal conditions, and a second trace 604 indicating the actual output voltage accounting for reflections.

In comparison to the graph 500 of FIG. 5, trace 604 is more “well-behaved” than trace 504. Whereas trace 504 has many relatively large oscillations and jumps in voltage, trace 604 is closer to a linear and gradual increase of the actual output voltage over the nine steps illustrated (where each step can correspond to the closing of a switch to connect a parallel impedance to the output, as described with respect to FIGS. 1-4). As a result, after each step-increase in the driver output voltage (illustrated by the first trace 602), the actual output voltage (second trace 604) oscillates for a short period with a relatively small magnitude (approximately 0.01V), then jumps about 0.05V. This is repeated nine times, in this example, over approximately 35 ns. Accordingly, in comparison to the single-step illustrated in the graph 500 of FIG. 5, the oscillations and jumps in the actual output voltage are about one-tenth or less in the graph 600 comparatively.

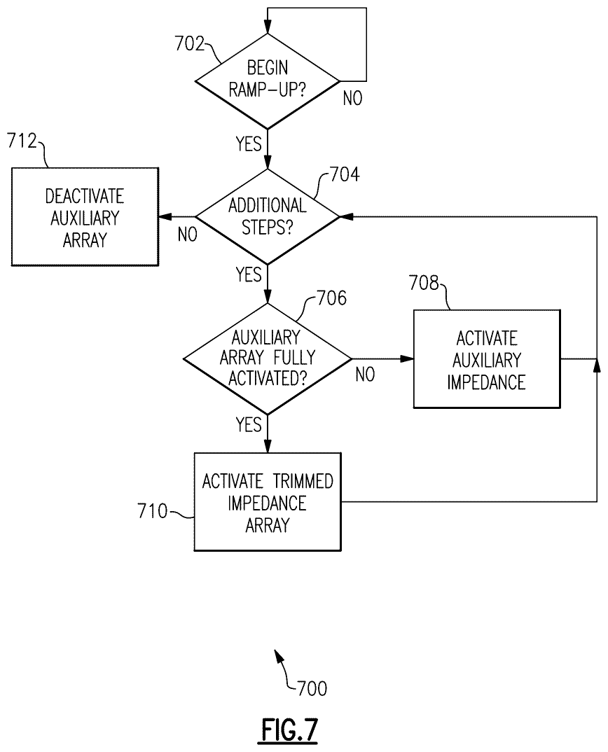

FIG. 7 illustrates a process 700 for managing a step-up process according to an example.

At act 702, a controller determines whether the ramp-up procedure has begun (e.g., the driver and/or device is preparing to transmit or has begun a transmission). If the controller determines the ramp-up procedure has begun (702 YES), the process may continue to act 704. If the controller determines the ramp-up procedure has not begun (702 NO), the process 700 may return to or remain at act 702 and continue to check (at intervals or in response to triggers) for the ramp-up procedure to begin.

At act 704, the controller determines whether there are additional steps. For example, if there are supposed to be five steps (e.g., five impedances connected in parallel in sequence, as described above with respect to FIGS. 3 and 4), but only three steps have been completed (e.g., only three impedance have been connected in parallel), then the controller may determine more steps are needed. On the other hand, if the controller determines that five impedances have been connected in parallel, then the controller may determine no further steps are needed. The number of steps may be arbitrary, so the controller may determine whether additional steps are required based on how many impedances are connected in parallel (e.g., how many impedances have been activated). In some examples, the controller may determine that no further steps are required if the trimmed impedance array has been activated. If the controller determines additional steps are required (704 YES), the process 700 may continue to act 706. If the controller determines additional steps are not required (704 NO), the process 700 may continue to act 712.

At act 706, the controller determines whether the auxiliary impedance array has been fully activated. For example, the controller may determine that not every impedance in the auxiliary array has been activated, and thus the auxiliary array is not fully activated. Alternatively, the controller may determine that every impedance in the auxiliary array has been activated, and thus the auxiliary array is fully activated. If the controller determines the auxiliary array is fully activated (706 YES), the process 700 may continue to act 710. If the controller determines the auxiliary array is not fully activated (706 NO), the process 700 may continue to act 708.

At act 708, the controller may activate an impedance of the auxiliary array (e.g., by closing an associated switch). For example, with reference to FIG. 3, the controller may activate the first impedance 326 by closing the first switch 318 which is coupled to the first impedance 326. The process 700 may then return to act 704 to determine if further steps are required.

At act 710, the controller activates the trimmed impedance array (e.g., trimmed impedance array 350 or 450). The controller may provide a code, for example a code stored in one-time programmable (OTP) memory or other memory, to the trimmed impedance array. The code may indicate which switches of the trimmed impedance array should be closed so that as soon as the trimmed impedance array is activated it is in its final state (e.g., no more internal switches within the trimmed impedance array will need to be closed). The process 700 may then continue to act 704.

Returning to act 704, as stated earlier, when the controller has determined that no further steps are required (704 NO), the process 700 may continue to act 712.

At act 712, the controller may deactivate all of the impedances of the auxiliary array, leaving only the trimmed impedance array active.

Transistors discussed herein may be any other type of switching device, including complex switching circuits, relays, switches with one or more poles and/or one or more throws, and so forth.

Transistors discussed herein may be p-type or n-type. In some examples, a given switch may be coupled to two p-type transistors, two n-type transistors, or one p-type and one n-type transistor.

In some examples discussed herein, for any given pair of transistors coupled to a given switch, only one of the transistors will be in a conducting state at a time. For example, if the first transistor 302 of FIG. 3 is in a conducting state, then the second transistor 304 may be in an open (e.g., non-conducting) state.

In examples discussed herein where transistors function as switches and switches are omitted, in general at least one transistor should be in a conducting (e.g., closed state) for the transistor to establish the conducting path. For example, with respect to FIG. 3, if the first transistor 302 is in a conducting state and is directly coupled to the first impedance 326 (i.e., the first switch 318 is omitted), then a conducting path exists through the first impedance 326 to the output 334.

In some examples discussed herein, the transistors may be part of respective drivers or a driver circuit.

In some examples, the switches (such as the switches of the auxiliary arrays or trimmed arrays) may have some corresponding impedance. The impedance of the switches may be taken into account when determining the values of the impedances coupled to those switches. For example, the first impedance 326 may have its value chosen based on the impedance of the first switch 318 of FIG. 3, in which that the impedance of the first switch 318 does not affect (or does not significantly affect) the target impedance of the auxiliary array 340. In some examples, the value of the impedances may be reduced and/or increased to account for the impedance of the switches.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the controllers 136, 236, 336, 426 may execute various operations discussed above. Using data stored in associated memory and/or storage, the controller 136, 236, 336, 426 also executes one or more instructions stored on one or more non-transitory computer-readable media, which the controller 136, 236, 336, 426 may include and/or be coupled to, that may result in manipulated data. In some examples, the controller 136, 236, 336, 426 may include one or more processors or other types of controllers. In one example, the controller 136, 236, 336, 426 is or includes at least one processor. In another example, the controller 136, 236, 336, 426 performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A system for ramping an impedance, comprising:
a trimmed array;
an auxiliary array;
at least one driver coupled to at least one of the trimmed array or the auxiliary array;
an output coupled to the trimmed array and the auxiliary array; and
at least one controller coupled to the at least one driver, the trimmed array, and the auxiliary array, the at least one controller configured to
control the at least one driver to provide a drive voltage to at least one of the trimmed array or the auxiliary array,
control the auxiliary array to activate in a series of sequential steps, and
control the trimmed array to activate in a single step, the trimmed array having a target impedance responsive to activation.

2. The system of claim 1 wherein the trimmed array includes:
one or more switches;
one or more impedances, each impedance of the one or more impedances coupled in series with a respective switch of the one or more switches;
at least one array input coupled to the one or more switches; and
an array output coupled to the one or more impedances.

3. The system of claim 2 wherein controlling the trimmed array to activate includes the at least one controller controlling a subset of the one or more switches to be in a closed state, wherein responsive to the subset of the one or more switches being in the closed state a corresponding subset of the one or more impedances are connected in parallel with one-another with respect to the array output, a total impedance of a parallel combination of the subset of one or more impedances equaling the target impedance.

4. The system of claim 2 wherein the at least one controller is coupled to the one or more switches.

5. The system of claim 1 wherein the auxiliary array includes:
one or more switches;
one or more impedances, each impedance of the one or more impedances coupled in series with a respective switch of the one or more switches;
at least one array input coupled to the one or more switches; and
an array output coupled to the one or more impedances.

6. The system of claim 4 wherein controlling the auxiliary array to activate includes the at least one controller sequential controlling each switch of the one or more switches to switch from an open state to a closed state over a period of time.

7. The system of claim 5 wherein the controller is coupled to the one or more switches.

8. The system of claim 1 wherein the driver includes a plurality of pairs of transistors, the auxiliary array includes one or more auxiliary switches, and the trimmed array includes one or more trim switches.

9. The system of claim 8 wherein each pair of transistors of the plurality of pairs of transistors is coupled to a respective switch of the one or more auxiliary switches.

10. The system of claim 8 wherein each pair of transistors of the plurality of pairs of transistors is coupled to a respective switch of the one or more trim switches.

11. The system of claim 8 wherein each pair of transistors of a first subset of the plurality of pairs of transistors is coupled to a respective switch of the one or more trim switches, and each pair of transistors of a second subset of the plurality of pairs of transistors is coupled to a respective switch of the one or more auxiliary switches.

12. The system of claim 1 wherein the at least one controller is further configured to deactivate the auxiliary array responsive to activating the trimmed array.

13. The system of claim 1 wherein, responsive to activating each auxiliary impedance of the auxiliary array, the auxiliary array has the target impedance.

14. A system for controlling reflections in a telecommunication circuit, comprising:
a transmitter configured to transmit a signal using a driver;
a receiver that can reflect a reflected signal based on the signal back to the transmitter;
an auxiliary array coupled between the transmitter and the receiver, the auxiliary array including a plurality of auxiliary impedances and a plurality of auxiliary switches, each auxiliary switch coupled to a respective auxiliary impedance;
a trimmed array coupled between the transmitter and the receiver, the trimmed array including a plurality of trimmed impedances and a plurality of trimmed switches, each trimmed switch coupled to a respective trimmed impedance; and
at least one controller coupled to the driver, the plurality of auxiliary switches, and the plurality of trimmed switches, the at least one controller configured to perform a set of operations including
sequentially controlling each auxiliary switch of the plurality of auxiliary switches to be in a closed state,
responsive to each auxiliary switch of the plurality of auxiliary switches being in the closed state, controlling a subset of the plurality of trimmed switches to be in the closed state, and
responsive to controlling the subset of the plurality of trimmed switches to be in the closed state, controlling each auxiliary switch of the plurality of auxiliary switches to be in an open state.

15. The system of claim 14 wherein the driver includes a plurality of pairs of transistors, each pair of transistors of the plurality of pairs of transistors being coupled to a respective switch of the plurality of auxiliary switches and the plurality of trimmed switches.

16. The system of claim 15 wherein the driver is coupled to each transistor of the plurality of pairs of transistors and is configured to provide a control signal to each respective gate of each respective transistor.

17. The system of claim 15 wherein a first transistor of each pair of transistors of the plurality of transistors is coupled to a first voltage bus, and a second transistor of each pair of transistors of the plurality of transistors is coupled a second voltage bus, a first voltage of the first voltage bus being greater than a second voltage of the second voltage bus.

18. The system of claim 14 wherein the at least one controller is configured to perform the set of operations responsive to determining that the transmitter is transmitting at least part of the signal.

19. The system of claim 14 wherein, responsive to closing each auxiliary switch of the plurality of auxiliary switches, the auxiliary array has a same impedance as the trimmed array responsive to the subset of the plurality of trimmed switches being in the closed state.

20. A method of adjusting an impedance in a total number of discrete steps, comprising:
providing a transmit signal at an output of a driver;
responsive to providing the transmit signal, sequentially closing each auxiliary switch of an auxiliary impedance array, each auxiliary switch being configured to couple a corresponding auxiliary impedance to the output;
responsive to closing all auxiliary switches of the auxiliary impedance array, closing a subset of trimmed switches of a trimmed impedance array, each trimmed switch being configured to couple a corresponding trimmed impedance to the output; and
responsive to closing the subset of trimmed switches, opening each auxiliary switch of the auxiliary impedance array.
